(19) United States
(12) Patent Application Publication
(10) Pub. No.: US 2024/0371825 A1
(43) Pub. Date: Nov. 7, 2024

(54) SEMICONDUCTOR PACKAGE AND METHOD FOR MAKING THE SAME

(71) Applicant: STATS ChipPAC Pte. Ltd., Singapore (SG)

(72) Inventors: TaeWoo LEE, Incheon (KR); HeeSoo LEE, Incheon (KR); EunHee MYUNG, Gyeonggi-do (KR)

(21) Appl. No.: 18/646,853

(22) Filed: Apr. 26, 2024

(30) Foreign Application Priority Data
May 5, 2023 (CN) 202310507117.8

(51) Int. Cl. H01L 25/065; H01L 23/00; H01L 23/31; H01L 23/498; H01L 23/538; H01L 25/00

(52) U.S. Cl. CPC H01L 25/0652; H01L 23/3121; H01L 23/49811; H01L 23/5383; H01L 24/32; H01L 24/83; H01L 25/50; H01L 24/16; H01L 2224/16145; H01L 2224/16225; H01L 2224/32225; H01L 2224/83

(57) ABSTRACT

A semiconductor package and a method for making the same are provided. The semiconductor package may include: a substrate having a first surface and a second surface opposite to the first surface; a first insulating layer disposed on the first surface of the substrate and having a first concave portion; a first semiconductor interposer disposed in the first concave portion of the first insulating layer, the first semiconductor interposer including a first semiconductor layer and a plurality of first wiring patterns formed on the first semiconductor layer; a first electronic component overlapping with a first portion of the first semiconductor interposer and electrically connected with the first wiring patterns of the first semiconductor interposer; and a second electronic component overlapping with a second portion of the first semiconductor interposer and electrically connected with the first wiring patterns of the first semiconductor interposer.

### TECHNICAL FIELD

The present application generally relates to semiconductor technology, and more particularly, to a semiconductor package and a method for making the same.

### BACKGROUND OF THE INVENTION

The semiconductor industry is constantly faced with complex integration challenges as consumers want their electronics to be smaller, faster and higher performance with more and more functionalities packed into a single device. To solve this problem, a chiplet-based package is introduced to form a system-on-chip (SoC). In the chiplet-based package, multiple small chips are connected to create a single, complex integrated circuit. The chiplet-based package offers several benefits over traditional monolithic SoCs, including improved performance, reduced power consumption, and increased design flexibility. However, the small chips in the chiplet-based package are interconnected through a packaging process, resulting low integration density and low performance.

Therefore, a need exists for a chiplet-based package with higher integration density and improved performance.

### SUMMARY OF THE INVENTION

An objective of the present application is to provide a semiconductor package with higher integration density and/or improved performance.

According to an aspect of embodiments of the present application, a semiconductor package is provided. The semiconductor package may include: a substrate having a first surface and a second surface opposite to the first surface; a first insulating layer disposed on the first surface of the substrate and having a first concave portion; a first semiconductor interposer disposed in the first concave portion of the first insulating layer, the first semiconductor interposer including a first semiconductor layer and a plurality of first wiring patterns formed on the first semiconductor layer; a first electronic component overlapping with a first portion of the first semiconductor interposer and electrically connected with the first wiring patterns of the first semiconductor interposer; and a second electronic component overlapping with a second portion of the first semiconductor interposer and electrically connected with the first wiring patterns of the first semiconductor interposer.

According to another aspect of embodiments of the present application, a method for making a semiconductor package is provided. The method may include: providing a substrate, the substrate having a first surface and a second surface opposite to the first surface; forming a first insulating layer on the first surface of the substrate, the first insulating layer having a first concave portion formed therein; embedding a first semiconductor interposer into the first concave portion of the first insulating layer, the first semiconductor interposer including a first semiconductor layer and a plurality of first wiring patterns formed on the first semiconductor layer; mounting a first electronic component on the first semiconductor interposer, the first electronic component overlapping with a first portion of the first semiconductor interposer and being electrically connected with the first wiring patterns of the first semiconductor interposer; and mounting a second electronic component on the first semiconductor interposer, the second electronic component overlapping with a second portion of the first semiconductor interposer and being electrically connected with the first wiring patterns of the first semiconductor interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view illustrating a semiconductor package according to an embodiment of the present application.

FIG. 1B is an enlarged view of a portion of the semiconductor package shown in FIG. 1A.

FIG. 2 is a cross-sectional view illustrating a semiconductor package according to another embodiment of the present application.

FIG. 3 is a cross-sectional view illustrating a semiconductor package according to another embodiment of the present application.

FIG. 4 is a cross-sectional view illustrating a semiconductor package according to another embodiment of the present application.

FIGS. 5A to 5J are cross-sectional views illustrating various steps of a method for making a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

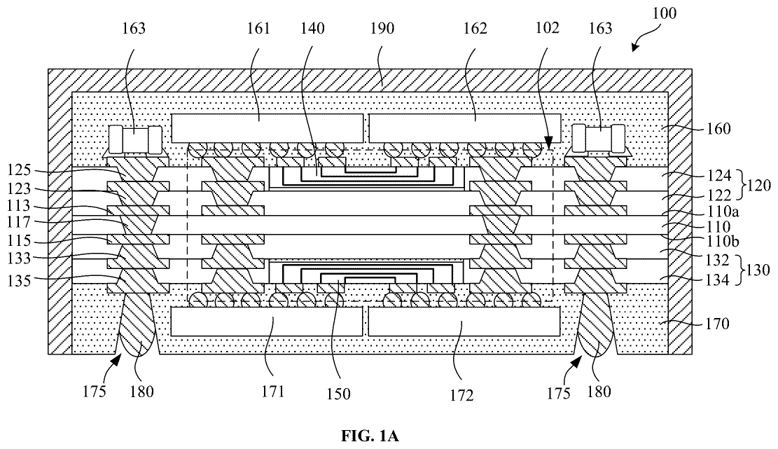

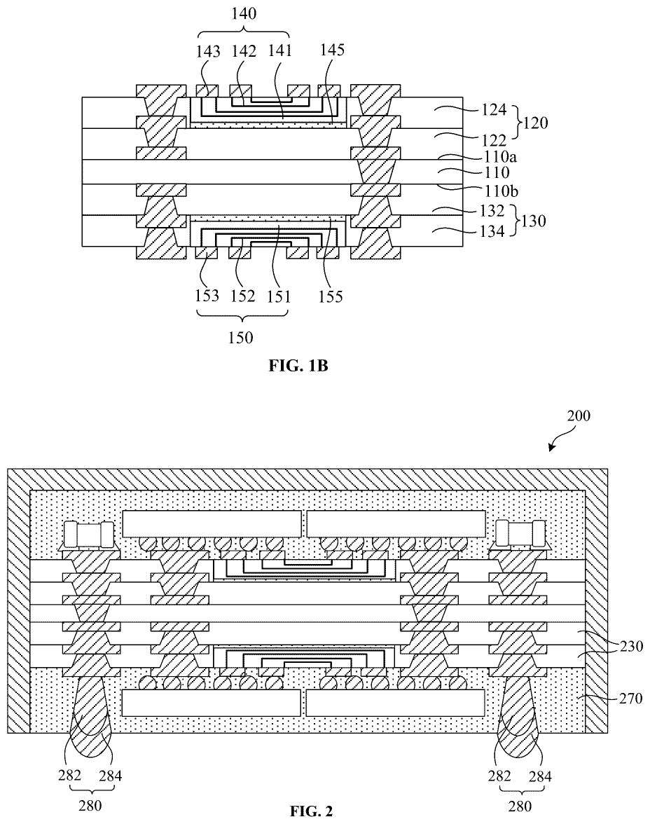

Referring to FIG. 1A, a cross-sectional view of a semiconductor package 100 is illustrated according to an embodiment of the present application.

As shown in FIG. 1A, the semiconductor package 100 may include a substrate 110, a first insulating layer 120 disposed on a first surface 110a of the substrate 110, a first semiconductor interposer 140 disposed in a first concave portion of the first insulating layer 120, a first electronic component 161 and a second electronic component 162 mounted on the first semiconductor interposer 140. The first electronic component 161 may overlap with a first portion of the first semiconductor interposer 140, and the second electronic component 162 may overlap with a second portion of the first semiconductor interposer 140, such that the first electronic component 161 and the second electronic component 162 may be electrically connected with each other through wiring patterns formed in the first semiconductor interposer 140. In an example, the semiconductor package 100 is a chiplet-based package, and the first electronic component 161 and the second electronic component 162 are small chips with different functionalities. The first semiconductor interposer 140 can be formed using integrated circuit (IC) manufacturing processes and can provide a fine pitch for wiring patterns used in signal and power distribution. Thus, the first semiconductor interposer 140 can provide high connectivity between the first electronic component 161 and the second electronic component 162, and the integration density and the performance of the semiconductor package 100 can be improved.

Specifically, the substrate 110 can provide support and connectivity for electronic components and devices. By way of example, the substrate 110 can include a printed circuit board (PCB), a carrier substrate, a semiconductor substrate with electrical interconnections, or a ceramic substrate. However, the substrate 110 is not to be limited to these examples. In other examples, the substrate 110 may include a laminate interposer, a strip interposer, a leadframe, or other suitable substrates.

In some embodiments, the substrate 110 may include a plurality of interconnection structures. The interconnection structures can provide connectivity for electronic components mounted on the substrate 110. The interconnection structures may define pads, traces and plugs through which electrical signals or voltages can be distributed horizontally and vertically across the substrate 110. For example, as shown in FIG. 1A, the interconnection structures may provide contact pads 113 and contact pads 115 along the first surface 110a and the second surface 110b of the substrate 110, respectively. The interconnection structures may further include one or more conductive vias 117 electrically connected with the contact pads 113 and contact pads 115, such that electronic components mounted on the contact pads 113 and electronic components mounted on the contact pads 115 can be electrically connected with each other via the conductive vias 117.

Referring to FIG. 1A, a first insulating layer 120 is formed on the first surface 110a of the substrate 110. The first insulating layer 120 may include one or more insulating sub-layers. The insulating layers may include an insulating material, for example, phenol or epoxy glass resin, a prepreg, or polyimide. In some embodiments, one or more conductive patterns may be formed in the first insulating layer 120. The conductive patterns may include one or more of Cu, Al, Sn, Ni, Au, Ag, or any other suitable electrically conductive materials.

In the example shown in FIG. 1A, the first insulating layer 120 includes a first insulating sub-layer 122 and a second insulating sub-layer 124 formed on the first insulating sub-layer 122. A plurality of through holes are formed in the first insulating sub-layer 122 to expose the contact pads 113 on the first surface 110a of the substrate 110, and a conductive material is filled into the through holes to form a first conductive layer 123 such as a redistribution layer (RDL). The first conductive layer 123 may have a vertical portion filing the through holes in the first insulating sub-layer 122 and a lateral portion disposed on the upper surface of the first insulating sub-layer 122. The vertical portion of the first conductive layer 123 may be electrically connected with the contact pads 113 on the first surface 110a of the substrate 110, and the lateral portion of the first conductive layer 123 may define contact pads or traces on the upper surface of the first insulating sub-layer 122. Similarly, a second conductive layer 125 is formed in the second insulating sub-layer 124. The second conductive layer 125 may have a vertical portion electrically connected with the first conductive layer 123, and a lateral portion defining contact pads or traces on the upper surface of the second insulating sub-layer 124. The first conductive layer 123 and the second conductive layer 125 collectively provide connectivity for electronic components mounted on the upper surface of the second insulating sub-layer 124, and can reroute the contact pads 113 on the substrate 110 to desired locations on the upper surface of the second insulating sub-layer 124.

Although the first insulating layer 120 may include two insulating sub-layers 122 and 124 as illustrated in FIG. 1A, the present application is not limited thereto. For example, the first insulating layer 120 may be a single layer, or include three or more insulating sub-layers.

FIG. 1B illustrates an enlarged view of a portion 102 of the semiconductor package 100 shown in FIG. 1A according to an embodiment of the present application. Referring to both FIG. 1A and FIG. 1B, the first insulating layer 120 has a first concave portion, and a first semiconductor interposer 140 is disposed in the first concave portion.

Specifically, in the example shown in FIG. 1B, the first insulating layer 120 includes two insulating sub-layers 122 and 124, and the first concave portion is a window formed in the second insulating sub-layer 124. A first adhesive 145 is attached to the upper surface of the first insulating sub-layer 122, and then the first semiconductor interposer 140 is attached to the first insulating sub-layer 122 by the first adhesive 145. The first adhesive 145 may include a non-conductive film, an anisotropic conductive film, an ultraviolet (UV) film, an instant adhesive, a thermosetting adhesive, or any other suitable adhesive materials. The first semiconductor interposer 140 may be a silicon-based interposer or include other semiconductor-based materials. The first semiconductor interposer 140 may be fabricated using any suitable IC manufacturing processes and can offer various advantages. For example, the first semiconductor interposer 140 can support fine pitches for through-silicon vias (TSVs) and traces used in signal and power distribution, and may have a thermal expansion coefficient which can match that of the semiconductor die or chiplet it is in contact with.

In the example shown in FIG. 1B, the first semiconductor interposer 140 may include a first semiconductor layer 141, a plurality of first wiring patterns 142 formed on the first semiconductor layer 141, and a plurality of contact pads 143 connected with the first wiring patterns 142. The first wiring patterns 142 may include TSVs and traces with fine pitches, and are electrically connected to the contact pads 143. The first wiring patterns 142 may be formed in a passivation layer such as an oxide layer or a nitride layer. The passivation layer can protect the first wiring patterns 142 from external physical and chemical damages. The contact pads 143 may be formed on the passivation layer, and provide connectivity for electronic components mounted thereon.

In some embodiments, the first semiconductor interposer 140 may be an active interposer, that is, there may be an active device or component, such as an integrated circuit or a semiconductor device, formed in the first semiconductor layer 141. In some embodiments, the first semiconductor interposer 140 may be a non-active or passive interposer, that is, there may be no active device or component formed in the first semiconductor interposer 140.

Continuing referring to FIG. 1A, a first electronic component 161 and a second electronic component 162 are mounted above the first insulating layer 120. The first electronic component 161 and the second electronic component 162 may include any of a variety of types of semiconductor dice, semiconductor packages, or discrete devices. For example, the first electronic component 161 and the second electronic component 162 may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), etc. In some embodiments, the first electronic component 161 and/or the second electronic component 162 may be small IC chips that contain different well-defined subsets of functionalities, and allow to integrate a variety of different architectures, different process nodes, and even dedicated silicon blocks or intellectual property (IP) blocks from different foundries into a single package.

The first electronic component 161 and the second electronic component 162 can be mounted on the first semiconductor interposer 140 by flip-chip bonding or any other suitable surface mounting techniques. In the example shown in FIG. 1A and FIG. 1B, the first electronic component 161 and the second electronic component 162 are mounted on the first semiconductor interposer 140 using respective solder bumps. Specifically, the first electronic component 161 may overlap with a first portion (i.e., the left portion shown in FIG. 1A) of the first semiconductor interposer 140, and is electrically connected some contact pads 143 of the first semiconductor interposer 140. The second electronic component 162 may overlap with a second portion (i.e., the right portion shown in FIG. 1A) of the first semiconductor interposer 140, and is electrically connected with some other contact pads 143 of the first semiconductor interposer 140. Thus, the first electronic component 161 and the second electronic component 162 can be electrically connected with each other via the contact pads 143 and the first wiring patterns 142 of the first semiconductor interposer 140. Moreover, some solder bumps of the first electronic component 161 and/or the second electronic component 162 may be electrically connected with the lateral portion of the second conductive layer 125 formed on the first insulating layer 120.

In the example shown in FIG. 1A, there are also two discrete devices 163 electrically connected with the lateral portion of the second conductive layer 125. However, the present application is not limited to the above examples. In some other embodiments, there may be more or less electronic components (such as semiconductor dice, semiconductor packages, or discrete devices) mounted on the first semiconductor interposer 140 and/or the first insulating layer 120.

Referring to FIG. 1A, a first encapsulant 160 is formed on the first insulating layer 120 and the first semiconductor interposer 140 to cover the first electronic component 161, the second electronic component 162 and the discrete devices 163. The first encapsulant 160 can be made from, for example, an epoxy molding compound (EMC), or polymide compound, and can provide mechanical protection, environmental protection, and a hermetic seal for electronic components and structures in the semiconductor package 100.

The semiconductor package 100 shown in FIG. 1A is a double side molded package, and further incudes a second insulating layer 130 disposed on the second surface 110b of the substrate 110, a second semiconductor interposer 150 disposed in a second concave portion of the second insulating layer 130, a third electronic component 171 and a fourth electronic component 172 mounted on the second semiconductor interposer 150.

The second insulating layer 130 may include a third insulating sub-layer 132 and a fourth insulating sub-layer 134 formed on the third insulating sub-layer 132. A plurality of through holes are formed in the third insulating sub-layer 132 to expose the contact pads 115 on the second surface 110b of the substrate 110, and a conductive material is filled into the through holes to form a third conductive layer 133. Similarly, a fourth conductive layer 135 is formed in the fourth insulating sub-layer 124. The third conductive layer 133 and the fourth conductive layer 135 collectively provide connectivity for electronic components mounted on the surface of the fourth insulating sub-layer 134, and can reroute the contact pads 115 on the second surface 110b of the substrate 110 to desired locations on the surface of the fourth insulating sub-layer 134.

Referring to both FIG. 1A and FIG. 1B, the second insulating layer 130 has a second concave portion, and a second semiconductor interposer 150 is disposed in the second concave portion. Specifically, the second concave portion may be a window formed in the fourth insulating sub-layer 134. A second adhesive 155 is attached to a surface of the third insulating sub-layer 132, and the second semiconductor interposer 150 is attached to the third insulating sub-layer 132 by the second adhesive 155.

As shown in FIG. 1B, the second semiconductor interposer 150 may include a second semiconductor layer 151, a plurality of second wiring patterns 152 formed on the second semiconductor layer 151, and a plurality of contact pads 153 connected with the second wiring patterns 152. The third electronic component 171 and the fourth electronic component 172 can be mounted on the second semiconductor interposer 150 by flip-chip bonding or any other suitable surface mounting techniques. Referring to FIG. 1A and FIG. 1B, the third electronic component 171 may overlap with a first portion of the second semiconductor interposer 150, and is electrically connected some contact pads 153 of the second semiconductor interposer 150. The fourth electronic component 172 may overlap with a second portion of the second semiconductor interposer 150, and is electrically connected with some other contact pads 153 of the second semiconductor interposer 150. Thus, the third electronic component 171 and the fourth electronic component 172 can be electrically connected with each other via the contact pads 153 and the second wiring patterns 152 of the second semiconductor interposer 150. Moreover, some solder bumps of the third electronic component 171 and/or the fourth electronic component 172 may be electrically connected with the lateral portion of the fourth conductive layer 135 formed on the second insulating layer 130.

Referring to FIG. 1A, a second encapsulant 170 is formed on the second insulating layer 130 and the second semiconductor interposer 150 to cover the third electronic component 171 and the fourth electronic component 172. The second encapsulant 170 may have a plurality of cavities 175 exposing a plurality of contact pads formed on the second insulating layer 130. For example, the exposed contact pads may be the lateral portion of the fourth conductive layer 135 formed in the second insulating layer 130.

A plurality of conductive bumps 180 may be formed in the plurality of cavities 175, respectively. In the example shown in FIG. 1A, the conductive bumps 180 are illustrated as solder bumps, but the present application is not limited thereto. In some other embodiments, the conductive bump 180 may include conductive pillars, or copper balls. In a case where the semiconductor package 100 is mounted on an external device or substrate, such as a printed circuit board (PCB), the conductive bumps 180 may be used for electrically connecting the semiconductor package 100 to the external device or substrate.

Moreover, as shown in FIG. 1A, an electromagnetic interference (EMI) shield 190 is formed to shield EMI induced to or generated by the semiconductor package 100. In some embodiments, the EMI shield 190 may be made of a conductive material such as copper, aluminum, iron, or any other suitable material for electromagnetic interference shielding. The EMI shield 190 may follow the shapes and/or contours of the first encapsulant 160, the first insulating layer 120, the substrate 110, the second insulating layer 130 and the second encapsulant 170. That is, the EMI shield 190 may cover the upper and lateral surfaces of the first encapsulant 160, and lateral surfaces of the first insulating layer 120, the substrate 110, the second insulating layer 130 and the second encapsulant 170.

Referring now to FIG. 2, a semiconductor package 200 is illustrated according to another embodiment of the present application. The semiconductor package 200 may be a double side molded package and have similar structures and configurations as the semiconductor package 100 shown in FIG. 1A. The similar or same parts between the semiconductor package 200 and the semiconductor package 100 will not be repeated herein.

The semiconductor package 200 of FIG. 2 is different from the semiconductor package 100 of FIG. 1A in that the semiconductor package 200 of FIG. 2 include stacked conductive solder bumps.

Specifically, as shown in FIG. 2, a plurality of conductive bumps 280 may be formed in a plurality of cavities formed in the second encapsulant 270. The cavities may expose contact pads formed on the lower surface of the second insulating layer 230. Each conductive bump 280 may include a first solder bump 282 in contact with a contact pad formed on the lower surface of the second insulating layer 230, and a second solder bump 284 formed on the first solder bump 282. The second solder bump 284 may protrude beyond the lower surface of the second encapsulant 270, so as to facilitate a bonding process of the semiconductor package 200 to an external device or substrate. In some embodiments, the second solder bump 284 may be at least partially reflowed, such that the first solder bump 282 and the second solder bump 284 can be melted together to form an integrated conductive bump 280.

Although each conductive bump 280 is illustrated as a stack of conductive solder bumps in the example shown in FIG. 2, there may be other examples that one or more conductive bumps 280 may include two or more stacked solder-encapsulated copper balls, two or more metallic core balls, etc.

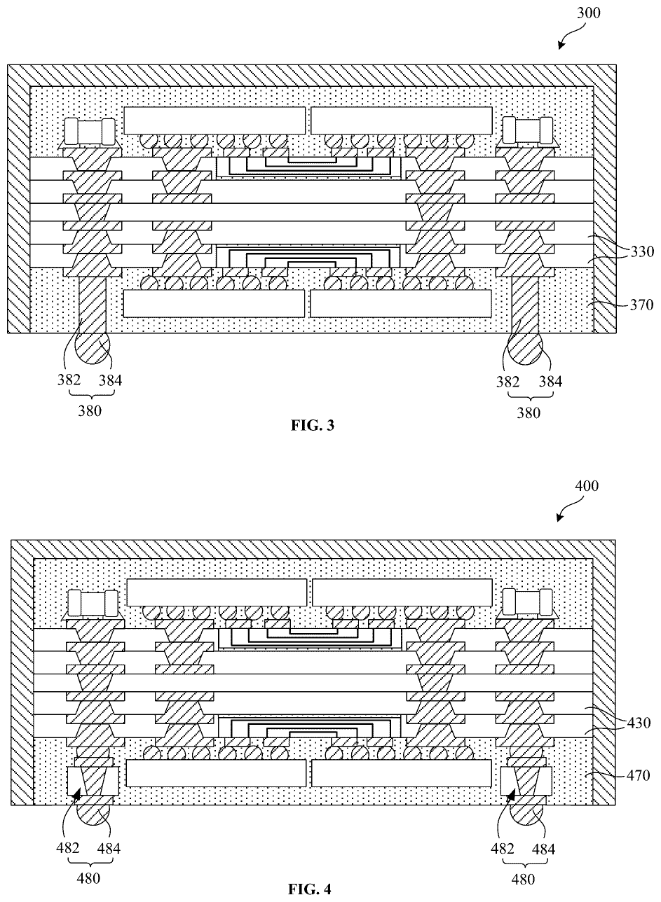

Referring now to FIG. 3, a semiconductor package 300 is illustrated according to another embodiment of the present application. The semiconductor package 300 may be a double side molded package and have similar structures and configurations as the semiconductor package 100 shown in FIG. 1A. The similar or same parts between the semiconductor package 300 and the semiconductor package 100 will not be repeated herein.

The semiconductor package 300 of FIG. 3 is different from the semiconductor package 100 of FIG. 1A in that the semiconductor package 300 of FIG. 3 includes a plurality of conductive pillars.

Specifically, as shown in FIG. 3, a plurality of conductive bumps 380 may be formed in a plurality of cavities formed in the second encapsulant 370. The cavities may expose contact pads formed on the lower surface of the second insulating layer 330. Each conductive bump 380 may include a conductive pillar 382 in contact with a contact pad formed on the lower surface of the second insulating layer 330, and a solder bump 384 formed on the conductive pillar 382. The lower surface of the conductive pillar 382 is substantially flush or coplanar with the lower surface of the second encapsulant 370. The conductive pillar 382 may include one or more of Cu, Al, Sn, Ni, Au, Ag, or other suitable electrically conductive material. In an example, the conductive pillar 382 may be a copper pillar, but aspects of the present application are not limited thereto.

Referring now to FIG. 4, a semiconductor package 400 is illustrated according to another embodiment of the present application. The semiconductor package 400 may be a double side molded package and have similar structures and configurations as the semiconductor package 100 shown in FIG. 1A. The similar or same parts between the semiconductor package 400 and the semiconductor package 100 will not be repeated herein.

The semiconductor package 400 of FIG. 4 is different from the semiconductor package 100 of FIG. 1A in that the semiconductor package 400 of FIG. 4 includes a plurality of e-bar conductive structures.

Specifically, as shown in FIG. 4, a plurality of conductive bumps 480 may be formed in a plurality of cavities formed in the second encapsulant 470. The cavities may expose contact pads formed on the lower surface of the second insulating layer 430. Each conductive bump 480 may include an e-bar conductive structure 482 in contact with a contact pad formed on the lower surface of the second insulating layer 430, and a solder bump 484 formed on the e-bar conductive structure 482. The lower surface of the e-bar conductive structure 482 is substantially flush or coplanar with the lower surface of the second encapsulant 470. In some embodiments, the e-bar conductive structure 482 may include an insulating substrate and a conductive via formed through the insulating substrate. In some embodiments, contact pads are formed on the upper and lower surfaces of the e-bar conductive structure 482, and a solder material can be applied to the contact pad to mechanically and electrically connect the e-bar conductive structure 482 to the contact pad formed on the lower surface of the second insulating layer 430.

According to another aspect of the present application, a method for making a semiconductor package is provided. The method may be used to make any of the semiconductor packages shown in FIGS. 1A, 1B and 2 to 4, for example.

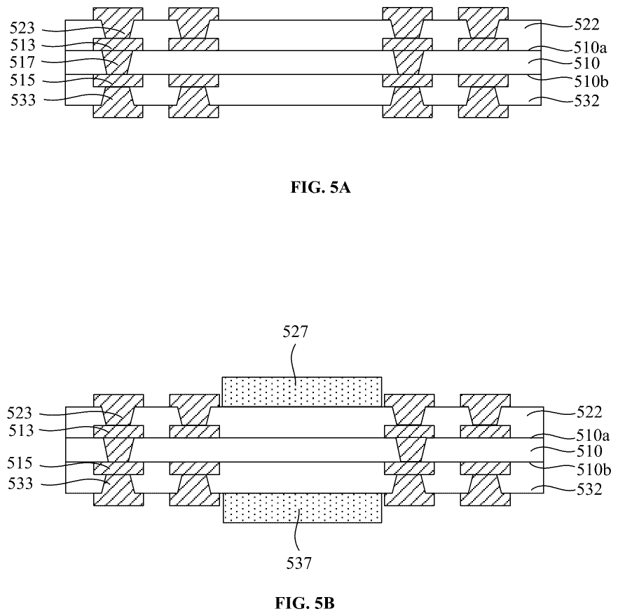

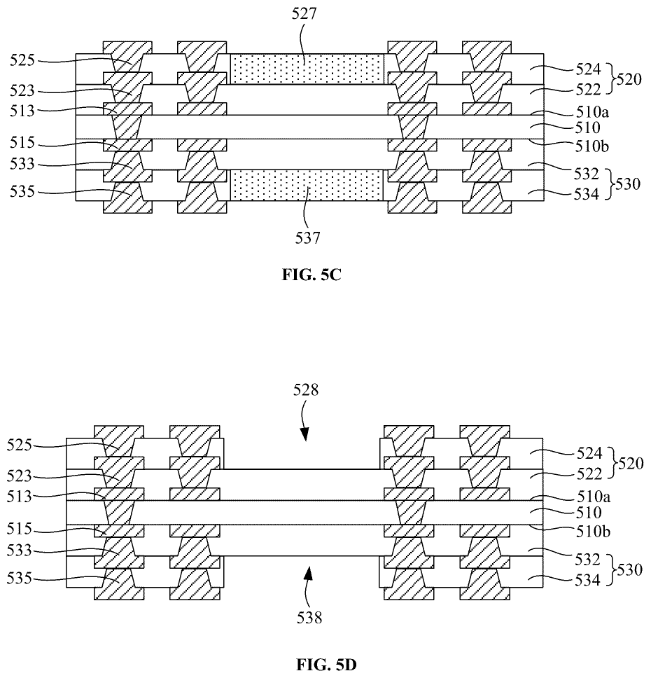

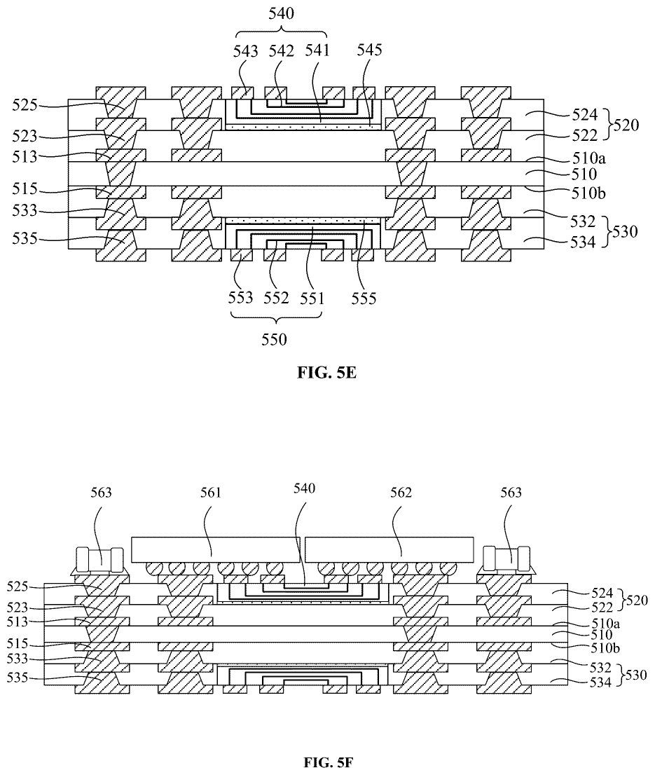

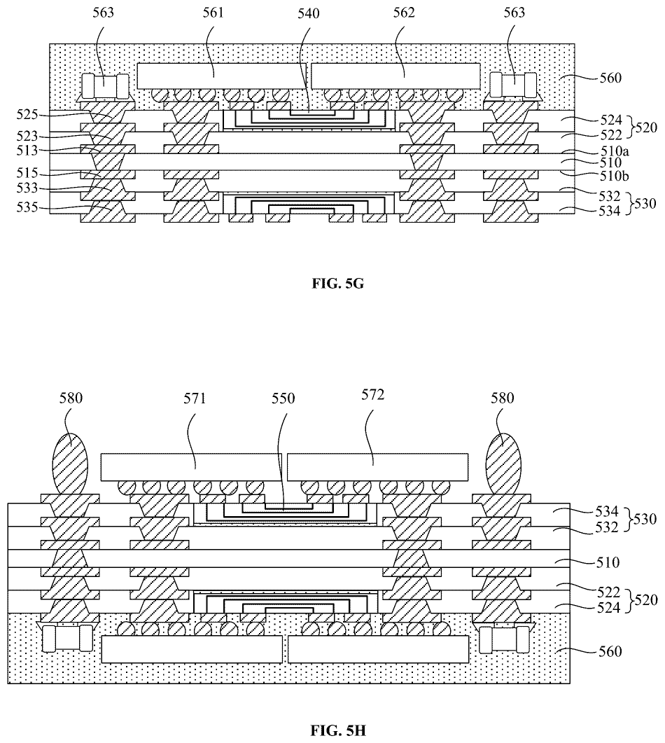

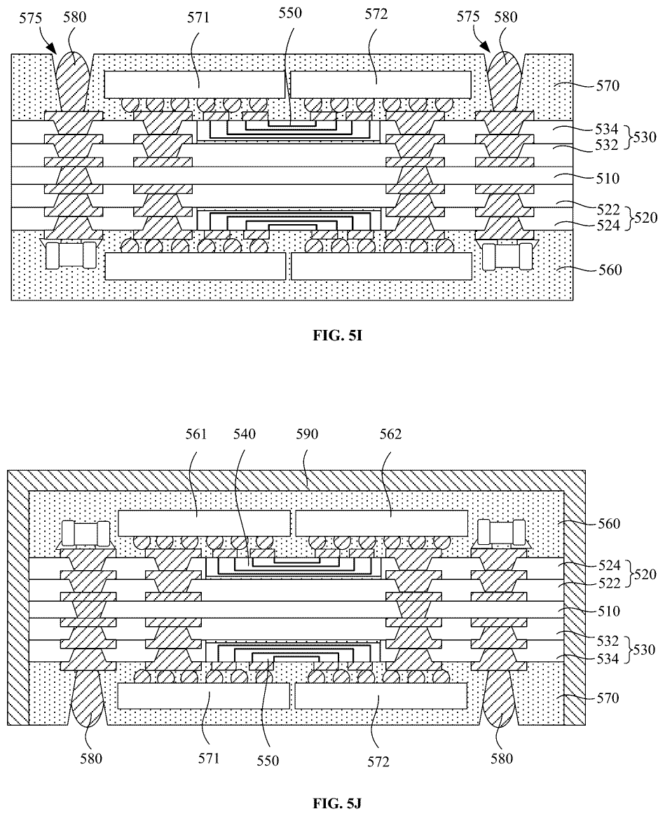

Referring to FIGS. 5A-5J, cross-sectional views illustrating a method for making a semiconductor package are shown according to an embodiment of the present application. For example, the method may be used to make the semiconductor package 100 shown in FIG. 1A.

As shown in FIG. 5A, a substrate 510 is provided. The substrate 510 has a first surface 510a and a second surface 510b opposite to the first surface 510a. Then, a first insulating sub-layer 522 is formed on the first surface 510a of the substrate 510, and a third insulating sub-layer 532 is formed on the second surface 510b of the substrate 510.

Specifically, the substrate 510 can provide support and connectivity for electronic components and devices. In some embodiments, the substrate 510 may include a plurality of interconnection structures. The interconnection structures can provide connectivity for electronic components mounted on the substrate 510. The interconnection structures may define pads, traces and plugs through which electrical signals or voltages can be distributed horizontally and vertically across the substrate 510. For example, as shown in FIG. 5A, the interconnection structures may provide contact pads 513 and contact pads 515 along the first surface 510a and the second surface 510b of the substrate 510, respectively. The interconnection structures may further include one or more conductive vias 517 electrically connected with the contact pads 513 and contact pads 515.

After the first insulating sub-layer 522 is formed on the first surface 510a of the substrate 510, a laser ablation process or an etching process may be performed to form a plurality of through holes in the first insulating sub-layer 522 to expose the contact pads 513 on the first surface 510a of the substrate 510. Then, a conductive material is filled into the through holes to form a first conductive layer 523 such as a redistribution layer (RDL). The first conductive layer 523 may have a vertical portion filing the through holes in the first insulating sub-layer 522 and a lateral portion disposed on the upper surface of the first insulating sub-layer 522. In an example, the lateral portion of the first conductive layer 523 are formed by depositing the conductive material into openings of a mask layer. The lateral portion of the first conductive layer 523 may define contact pads or traces on the upper surface of the first insulating sub-layer 522. Similar processes may be performed on the third insulating sub-layer 532 to form a third conductive layer 533 in the third insulating sub-layer 532.

Referring to FIG. 5B, a first sacrificial pattern 527 is formed on the first insulating sub-layer 522, and a second sacrificial pattern 537 is formed on the third insulating sub-layer 532.

In some examples, the first sacrificial pattern 527 and the third insulating sub-layer 532 may include a dry film. The dry film may include a polymer and can be adhered to the first insulating sub-layer 522 or the third insulating sub-layer 532. However, the present application is not limited to the above examples, and the first sacrificial pattern 527 and the third insulating sub-layer 532 can be made of other material which can be adhered to the first insulating sub-layer 522 and the third insulating sub-layer 532 and can be easily removed therefrom. For example, the sacrificial patterns may be formed of a photo resist layer which can be subsequently patterned using lithographic techniques.

Referring to FIG. 5C, a second insulating sub-layer 524 is formed on the first insulating sub-layer 522 and around the first sacrificial pattern 527, and a fourth insulating sub-layer 534 is formed on the third insulating sub-layer 532 and around the second sacrificial pattern 537.

The second insulating sub-layer 524 and the fourth insulating sub-layer 534 can be formed by processes similar as those for forming the first insulating sub-layer 522 and the third insulating sub-layer 532. A second conductive layer 525 is formed in the second insulating sub-layer 524, and a fourth conductive layer 535 is formed in the fourth insulating sub-layer 534. The first conductive layer 523 and the second conductive layer 525 collectively provide connectivity for electronic components mounted on an upper surface of the second insulating sub-layer 524, and the third conductive layer 533 and the fourth conductive layer 535 collectively provide connectivity for electronic components mounted on a lower surface of the fourth insulating sub-layer 534.

Referring to both FIG. 5C and FIG. 5D, the first sacrificial pattern 527 is removed to form a first window 528 in the second insulating sub-layer 524, and the second sacrificial pattern 537 is removed to form a second window 538 in the fourth insulating sub-layer 534. In some embodiments, the first sacrificial pattern 527 and the second sacrificial pattern 537 can be peeled off from the first insulating sub-layer 522 and the third insulating sub-layer 532. In some embodiments, a laser ablation process or an etching process may be employed to remove the first sacrificial pattern 527 and the second sacrificial pattern 537. The first window 528 may form a first concave portion in the first insulating layer 520 consisting of the first insulating sub-layer 522 and the second insulating sub-layer 524, and the second window 538 may form a second concave portion in the second insulating layer 530 consisting of the third insulating sub-layer 532 and the fourth insulating sub-layer 534.

Referring to FIG. 5D and FIG. 5E, a first semiconductor interposer 540 is embedded into the first concave portion (i.e., the first window 528) of the first insulating layer 520, and a second semiconductor interposer 550 is embedded into the second concave portion (i.e., the second window 538) of the second insulating layer 530.

In some embodiments, a first adhesive 545 is formed in the first concave portion of the first insulating layer 520, and then the first semiconductor interposer 540 is attached on the first adhesive 545 to embed the first semiconductor interposer 540 in the first concave portion of the first insulating layer 520. Similarly, a second adhesive 555 is formed in the second concave portion of the second insulating layer 530, and then the second semiconductor interposer 550 is attached on the second adhesive 555 to embed the second semiconductor interposer 550 in the second concave portion of the second insulating layer 530.

In some embodiments, the first semiconductor interposer 540 may include a first semiconductor layer 541, a plurality of first wiring patterns 542 formed on the first semiconductor layer 541, and a plurality of contact pads 543 connected with the first wiring patterns 542. The first wiring patterns 542 may include TSVs and traces with fine pitch, and be electrically connected to the contact pads 543. The first wiring patterns 542 may be formed in a passivation layer such as an oxide layer or a nitride layer. The contact pads 543 may be formed on the passivation layer, and provide connectivity for electronic components mounted thereon. Similarly, the second semiconductor interposer 550 may include a second semiconductor layer 551, a plurality of second wiring patterns 552 formed on the second semiconductor layer 551, and a plurality of contact pads 553 connected with the second wiring patterns 552.

Referring to FIG. 5F, a first electronic component 561 and a second electronic component 562 are mounted above the first insulating layer 520.

The first electronic component 561 and the second electronic component 562 can be mounted on the first semiconductor interposer 540 by flip-chip bonding or other suitable surface mounting techniques. For example, solder paste may be deposited or printed onto contact pads where the first electronic component 561 and the second electronic component 562 may be surface mounted. Then, the first electronic component 561 and the second electronic component 562 may be placed on the upper surface of the first insulating layer 520 with terminals of the first electronic component 561 and the second electronic component 562 in contact with and over the solder paste. The solder paste may be reflowed to mechanically and electrically couple the first electronic component 561 and the second electronic component 562 to the contact pads on the upper surface of the first insulating layer 520. The first electronic component 561 and the second electronic component 562 may include any of a variety of types of semiconductor dice, semiconductor packages, or discrete devices. Besides the first electronic component 561 and the second electronic component 562, there may be other electronic components (for example, the two discrete devices 563 shown in FIG. 5F) mounted on the first semiconductor interposer 540 and/or the first insulating layer 520.

Referring to both FIGS. 5E and 5F, the first electronic component 561 may overlap with a first portion (i.e., the left portion shown in FIG. 5F) of the first semiconductor interposer 540, and is electrically connected with some contact pads 543 of the first semiconductor interposer 540. The second electronic component 562 may overlap with a second portion (i.e., the right portion shown in FIG. 5F) of the first semiconductor interposer 540, and is electrically connected with some other contact pads 543 of the first semiconductor interposer 540. Thus, the first electronic component 561 and the second electronic component 562 can be electrically connected with each other via the contact pads 543 and the first wiring patterns 542 of the first semiconductor interposer 540 (also referring to FIG. 5E). Moreover, some solder bumps of the first electronic component 561 and/or the second electronic component 562 may be electrically connected with the lateral portion of the second conductive layer 525 formed on the first insulating layer 520.

Afterwards, referring to FIG. 5G, a first encapsulant 560 is formed on the first insulating layer 520 to encapsulate the first electronic component 561 and the second electronic component 562.

The first encapsulant 560 may be formed on the first insulating layer 520 using a compression molding process or an injection molding process. In some other embodiments, the first encapsulant 560 may be formed using paste printing, transfer molding, liquid encapsulant molding, vacuum lamination, spin coating, or other suitable process. The first encapsulant 560 may be made of polymer composite material, such as epoxy resin with filler, epoxy acrylate with filler, or polymer with proper filler, but the scope of this application is not limited thereto. In some examples, the first encapsulant 560 may be planarized, if desired.

Afterwards, referring to FIG. 5H, the package shown in FIG. 5G is flipped, and a third electronic component 571 and a fourth electronic component 572 are mounted on the second semiconductor interposer 550.

The third electronic component 571 and the fourth electronic component 572 can be mounted on the second semiconductor interposer 550 by flip-chip bonding or other suitable surface mounting techniques. Referring to both FIGS. 5E and 5H, the third electronic component 571 may overlap with a first portion of the second semiconductor interposer 550, and is electrically connected with some contact pads 553 of the second semiconductor interposer 550. The fourth electronic component 572 may overlap with a second portion of the second semiconductor interposer 550, and is electrically connected with some other contact pads 553 of the second semiconductor interposer 550. Thus, the third electronic component 571 and the fourth electronic component 572 can be electrically connected with each other via the contact pads 553 and the second wiring patterns 552 of the second semiconductor interposer 550.

In the example shown in FIG. 5H, a plurality of conductive bumps 580 are also formed on contact pads formed on the upper surface of the second insulating layer 530, and the conductive bumps 580 may be solder bumps. However, the present application is not limited thereto. In some other embodiments, the conductive bump 580 may include conductive pillars, or copper balls, and can be formed in subsequent steps.

Afterwards, referring to FIG. 5I, a second encapsulant 570 is formed on the second insulating layer 530 to encapsulate the third electronic component 571 and the fourth electronic component 572.

The second encapsulant 570 may be formed on the second insulating layer 530 using a compression molding process or an injection molding process. In some other embodiments, the second encapsulant 570 may be formed using paste printing, transfer molding, liquid encapsulant molding, vacuum lamination, spin coating, or other suitable process. Further, a laser ablation process or an etching process may be performed on the second encapsulant 570 to form a plurality of cavities 575 exposing the contact bumps 580 respectively, thus that the conductive bumps 580 can be used for electrically connecting this semiconductor package to the external device.

At last, referring to FIG. 5J, the package shown in FIG. 5I is flipped, and an EMI shield 590 is formed. The EMI shield 590 may be formed from copper, aluminum, iron, or any other suitable material for EMI shielding. In some embodiments, the EMI shield 590 may be formed by spray coating, plating, sputtering, or any other suitable metal deposition process. The EMI shield 590 may follow the shapes and/or contours of the first encapsulant 560, the first insulating layer 520, the substrate 510, the second insulating layer 530 and the second encapsulant 570.

While the method for making the semiconductor package of the present application is described in conjunction with corresponding FIGS. 5A to 5J, it will be understood by those skilled in the art that modifications and adaptations to the method may be made without departing from the scope of the present invention. For example, in a case that an additional solder bump is formed on the conductive bump 580 shown in FIG. 5J, the method described above can be used to make the semiconductor package 200 shown in FIG. 2. In another case that a plurality of conductive pillars (such as copper posts), rather than the solder bumps 580 shown in FIG. 5H, are formed on the second insulating layer 530, the method described above can be used to make the semiconductor package 300 shown in FIG. 3. In still another case that a plurality of e-bar conductive structures, rather than the solder bumps 580 shown in FIG. 5H, are formed on the second insulating layer 530, the method described above can be used to make the semiconductor package 400 shown in FIG. 4. In addition, although it is only illustrated a single unit of semiconductor package in the steps of FIGS. 5A to 5J, a strip type of semiconductor packages, i.e., various semiconductor packages formed in a substrate strip, can be made using the process shown in FIGS. 5A to 5J. For example, a singulation step may be performed to the strip before the step for forming the EMI shield as shown in FIG. 5J.

The discussion herein included numerous illustrative figures that showed various portions of a semiconductor package and method of manufacturing thereof. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate having a first surface and a second surface opposite to the first surface;
a first insulating layer disposed on the first surface of the substrate and having a first concave portion;
a first semiconductor interposer disposed in the first concave portion of the first insulating layer, the first semiconductor interposer comprising a first semiconductor layer and a plurality of first wiring patterns formed on the first semiconductor layer;
a first electronic component overlapping with a first portion of the first semiconductor interposer and electrically connected with the first wiring patterns of the first semiconductor interposer; and
a second electronic component overlapping with a second portion of the first semiconductor interposer and electrically connected with the first wiring patterns of the first semiconductor interposer.

2. The semiconductor package of claim 1, wherein the first insulating layer comprises a first insulating sub-layer and a second insulating sub-layer formed on the first insulating sub-layer, and the first concave portion of the first insulating layer comprises a first window formed in the second insulating sub-layer.

3. The semiconductor package of claim 1, further comprising:
a first adhesive disposed between the first semiconductor interposer and the first insulating layer.

4. The semiconductor package of claim 1, further comprising:
a first encapsulant disposed on the first insulating layer and encapsulating the first electronic component and the second electronic component.

5. The semiconductor package of claim 1, further comprising:
a second insulating layer disposed on the second surface of the substrate and having a second concave portion;
a second semiconductor interposer disposed in the second concave portion of the second insulating layer, the second semiconductor interposer comprising a second semiconductor layer and a plurality of second wiring patterns formed on the second semiconductor layer;
a third electronic component overlapping with a first portion of the second semiconductor interposer and electrically connected with the second wiring patterns of the second semiconductor interposer; and
a fourth electronic component overlapping with a second portion of the second semiconductor interposer and electrically connected with the second wiring patterns of the second semiconductor interposer.

6. The semiconductor package of claim 5, wherein the second insulating layer comprises a third insulating sub-layer and a fourth insulating sub-layer formed on the third insulating sub-layer, and the second concave portion of the second insulating layer comprises a second window formed in the fourth insulating sub-layer.

7. The semiconductor package of claim 5, further comprising:
a second adhesive disposed between the second semiconductor interposer and the second insulating layer.

8. The semiconductor package of claim 5, further comprising:
a second encapsulant disposed on the second insulating layer and encapsulating the third electronic component and the fourth electronic component, wherein the second encapsulant has a plurality of cavities exposing a plurality of contact pads formed on the second insulating layer respectively; and
a plurality of conductive bumps disposed in the plurality of cavities, respectively.

9. The semiconductor package of claim 8, wherein the conductive bump comprises a solder bump, a copper pillar, or an e-bar conductive structure.

10. A method for making a semiconductor package, comprising:
providing a substrate, the substrate having a first surface and a second surface opposite to the first surface;
forming a first insulating layer on the first surface of the substrate, the first insulating layer having a first concave portion formed therein;
embedding a first semiconductor interposer into the first concave portion of the first insulating layer, the first semiconductor interposer comprising a first semiconductor layer and a plurality of first wiring patterns formed on the first semiconductor layer;
mounting a first electronic component on the first semiconductor interposer, the first electronic component overlapping with a first portion of the first semiconductor interposer and being electrically connected with the first wiring patterns of the first semiconductor interposer; and
mounting a second electronic component on the first semiconductor interposer, the second electronic component overlapping with a second portion of the first semiconductor interposer and being electrically connected with the first wiring patterns of the first semiconductor interposer.

11. The method of claim 10, wherein forming the first insulating layer on the first surface of the substrate comprises:
forming a first insulating sub-layer on the first surface of the substrate;
forming a first sacrificial pattern on the first insulating sub-layer;
forming a second insulating sub-layer on the first insulating sub-layer and around the first sacrificial pattern; and
removing the first sacrificial pattern to form a first window in the second insulating sub-layer.

12. The method of claim 10, wherein embedding the first semiconductor interposer into the first concave portion of the first insulating layer comprises:
forming a first adhesive on a lower surface of the first concave portion of the first insulating layer; and
attaching the first semiconductor interposer on the first adhesive to embed the first semiconductor interposer into the first concave portion of the first insulating layer.

13. The method of claim 10, further comprising:
forming a first encapsulant on the first insulating layer to encapsulate the first electronic component and the second electronic component.

14. The method of claim 10, further comprising:
forming a second insulating layer on the second surface of the substrate, the second insulating layer having a second concave portion formed therein;
embedding a second semiconductor interposer into the second concave portion of the second insulating layer, the second semiconductor interposer comprising a second semiconductor layer and a plurality of second wiring patterns formed on the second semiconductor layer;
mounting a third electronic component on the second semiconductor interposer, the third electronic component overlapping with a first portion of the second semiconductor interposer and being electrically connected with the second wiring patterns of the second semiconductor interposer; and
mounting a fourth electronic component on the second semiconductor interposer, the fourth electronic component overlapping with a second portion of the second semiconductor interposer and being electrically connected with the second wiring patterns of the second semiconductor interposer.

15. The method of claim 14, wherein forming the second insulating layer on the second surface of the substrate comprises:
forming a third insulating sub-layer on the second surface of the substrate;
forming a second sacrificial pattern on the third insulating sub-layer;
forming a fourth insulating sub-layer on the third insulating sub-layer and around the second sacrificial pattern; and
removing the second sacrificial pattern to form a second window in the fourth insulating sub-layer.

16. The method of claim 14, wherein embedding the second semiconductor interposer into the second concave portion of the second insulating layer comprises:
forming a second adhesive on a lower surface of the second concave portion of the second insulating layer; and
attaching the second semiconductor interposer on the second adhesive to embed the second semiconductor interposer into the second concave portion of the second insulating layer.

17. The method of claim 14, further comprising:
forming a second encapsulant on the second insulating layer to encapsulate the third electronic component and the fourth electronic component, the second encapsulant having a plurality of cavities exposing a plurality of contact pads formed on the second insulating layer respectively; and
forming a plurality of conductive bumps in the plurality of cavities, respectively.

18. The method of claim 17, wherein the conductive bump comprises a solder bump, a copper pillar, or an e-bar conductive structure.
